(19) United States
(12) Patent Application Publication
(10) Pub. No.: US 2025/0164542 A1
(43) Pub. Date: May 22, 2025

(54) METHOD FOR CHECKING INSULATION BETWEEN LOW-VOLTAGE NETWORKS OF A VEHICLE, AND LOW-VOLTAGE SUPPLY ARRANGEMENT FOR A VEHICLE

(71) Applicant: Volkswagen Aktiengesellschaft, Wolfsburg (DE)

(72) Inventor: Bastian Weber, Hannover (DE)

(21) Appl. No.: 18/729,460

(22) PCT Filed: Dec. 15, 2022
(86) PCT No.: PCT/EP2022/086057

§ 371 Date: Jul. 16, 2024

(30) Foreign Application Priority Data
Jan. 20, 2022 (DE) 10 2022 200 600.3

(51) Int. Cl. G01R 31/14; B60L 3/00

(52) U.S. Cl. CPC G01R 31/14; B60L 3/0069; B60L 2210/10

(57) ABSTRACT

Technologies and techniques for checking insulation between low-voltage networks of a vehicle, wherein the low-voltage networks are galvanically separated and each comprise a DC/DC converter, an energy storage device, and a supply bus for supplying low-voltage consumers. The DC/DC converter is connected on one side to a high-voltage supply and on the other side to the energy storage device and the supply bus. The method includes: applying a voltage change to the high-voltage supply or the supply bus of one of the low-voltage networks using the DC/DC converter of said low-voltage network; detecting a voltage on each of the supply buses of at least the other low-voltage networks; evaluating the detected voltages; and deriving and outputting a test decision. A corresponding low-voltage supply arrangement is also disclosed.

### RELATED APPLICATIONS

The present application claims priority to International Patent App. No. PCT/EP2022/086057 to Bastian Weber, titled “Method For Checking Insulation Between Low-Voltage Networks Of A Vehicle, And Low-Voltage Supply Arrangement For A Vehicle”, filed Dec. 15, 2022, which claims priority to German Patent App. No. 10 2022 200 600.3, filed on Jan. 20, 2022, the contents of each being incorporated by reference in their entirety herein.

### TECHNICAL FIELD

The present disclosure relates to technologies and techniques for checking isolation between low-voltage networks of a vehicle and to a low-voltage supply arrangement for a vehicle.

### BACKGROUND

Automated driving without a human fallback level presents great challenges for automobile electrics. The energy demand of the surroundings sensors such as LIDAR, radar or cameras, together with control processors for data processing as well as trajectory planning, is considerable. The surroundings sensor system and control processor for data processing are presently supplied by a low-voltage battery (generally in 12-volt technology). This low-volt battery is fed by a power converter, which is connected to high-voltage wiring of a traction battery of the (electric) vehicle. It is also possible for several low-voltage networks to be provided. These low-voltage networks must be isolated with respect to one another.

A supply system is known from US 2020/0001806 A1. The system includes a first DC/DC converter arranged to output electrical power only to a first battery and to first loads in a first specified set. The first specified set includes loads provided to control and perform steering and braking. The system furthermore includes a second DC/DC converter arranged to output electrical power to loads isolated from the first loads provided to control and perform steering and braking.

A device for monitoring an onboard electrical system is known from DE 10 2015 200 174 A1, comprising at least one first sub-network having a first voltage and a further sub-network having a further voltage, comprising at least one coupling means for disconnectably connecting the two sub-networks, wherein at least one of the sub-networks includes an energy storage device, comprising at least one evaluation means for monitoring proper insulation of the two sub-networks, wherein at least one means for generating a characteristic signal is provided in the first sub-network, wherein at least one detection means for detecting the further voltage is arranged in the further sub-network, and wherein the evaluation means evaluates the further voltage for recognizing whether a typical magnitude of the characteristic signal is present in the further sub-network.

A method for monitoring an insulation state of a first high-voltage network and an insulation state of at least one further high-voltage network of a vehicle is known from DE 10 2017 204 885 A1, in which an individual insulation monitoring device is connected to the first high-voltage network and the at least one further high-voltage network, and in which initially a first insulation measurement is carried out at the first high-voltage network, and subsequently in each case a further insulation measurement is carried out at the at least one further high-voltage network, by means of the insulation monitoring device in a periodically recurring succession.

A vehicle and a method for checking the operational safety of the vehicle is known from DE 10 2011 083 600 A1. The vehicle is in particular an electric and/or hybrid vehicle. The vehicle comprises at least one sensor, which is designed to detect operational safety-relevant electrical variables. In the method for checking a vehicle, at least one operational safety-relevant electrical variable is detected by means of the sensor of the vehicle.

A device for insulation monitoring between a low-voltage network and a high-voltage network is known from DE 10 2013 226 595 A1, wherein the device can be connected both to a high-voltage positive connection and to a high-voltage negative connection as well as to the low-voltage network, wherein the device has a plurality of electrical contacts for coupling monitoring connections to the high-voltage circuit by means of a respective high-voltage positive connection and by means of a respective high-voltage negative connection, which can be connected in different sections of the high-voltage network.

Split vehicle power buses are known from DE 10 2019 117 619 A1. A system includes a first DC/DC converter arranged so as to output electrical power only to a first battery and to first loads in a first defined set. The first defined set includes loads provided to control and perform steering and braking. The system furthermore comprises a second DC/DC converter arranged so as to output electrical power to loads isolated from the first loads provided to control and perform steering and braking.

### SUMMARY

Aspects of the present disclosure are directed to technologies and techniques for checking insulation between low-voltage networks of a vehicle and a corresponding low-voltage supply arrangement for a vehicle.

Aspects of the present disclosure are described in the features recited in the independent claims, found below. Further aspects are described in the features recited in the dependent claims.

In some examples, a method is disclosed for checking insulation between low-voltage networks of a vehicle is made available, wherein the low-voltage networks are galvanically isolated from one another, and wherein each of the low-voltage networks comprises a DC/DC converter (DC to DC converter), an energy storage device and a supply bus for supplying, in particular safety-critical and not safety-critical, low-voltage consumers, wherein the DC/DC converter can be connected, or is connected, to a high-voltage supply system on the one hand and to the energy storage device and the supply bus on the other hand, comprising: impressing a voltage change on the high-voltage supply system or on the supply bus of one of the low-voltage networks by means of the DC/DC converter of this low-voltage network; detecting a respective voltage on the supply buses of at least the other low-voltage networks; evaluating the detected voltages; and deriving and outputting a checking decision.

In some examples, a low-voltage supply arrangement is disclosed for a vehicle, comprising low-voltage networks that are galvanically isolated from one another, wherein each of the low-voltage networks comprises a DC/DC converter, an energy storage device and a supply bus for supplying, in particular safety-critical and not safety-critical, low-voltage consumers, wherein the DC/DC converter can be connected, or is connected, to a high-voltage supply system on the one hand and to the energy storage device and the supply bus on the other hand, and a control device, wherein the control device is configured to carry out a check of insulation between low-voltage networks by activating the following measures: impressing a voltage change on the high-voltage supply system or on the supply bus of one of the low-voltage networks by means of the DC/DC converter of this low-voltage network; receiving a respective voltage detected on the supply buses of at least the other low-voltage networks; evaluating the detected voltages; and deriving and outputting a checking decision.

Further features regarding configurations of the low-voltage supply arrangement will be apparent from the description of designs of the method. The advantages of the low-voltage supply arrangement are in each case the same as with the designs of the method.

In some examples, a vehicle is also disclosed, comprising a low-voltage supply arrangement according any of the described embodiments. The vehicle may be configured as a motor vehicle, such as an electric or hybrid vehicle. The vehicle, however, can generally also be another (electrified) land vehicle, a rail vehicle, a watercraft, an aircraft or a space craft, for example a drone or an air taxi.

### BRIEF DESCRIPTION OF THE DRAWINGS

The present disclosure will be described in more detail hereafter based on preferred exemplary embodiments with reference to the figures. In the drawings:

FIG. 1 shows a schematic representation of embodiments of the low-voltage supply arrangement for a vehicle, according to some aspects of the present disclosure;

FIG. 2a shows a schematic representation of voltage curves on the supply buses of the low-voltage networks, according to some aspects of the present disclosure; and

FIG. 2b shows a schematic representation of voltage curves on the supply buses of the low-voltage networks, according to some aspects of the present disclosure.

### DETAILED DESCRIPTION

The method and low-voltage supply arrangement disclosed herein enable checking the insulation between low-voltage networks. One basic idea is to intentionally cause a voltage change-either an increase or a decrease-on the supply bus of one low-voltage network, while simultaneously detecting the voltage on the supply buses of other low-voltage networks. If the insulation between two low-voltage networks is intact, only the voltage on the supply bus of the network where the voltage change was induced will change; the voltage on the supply bus of the other network will remain unaffected. Conversely, if the insulation is defective, the induced voltage change will cause a corresponding voltage change on the supply bus of the other network due to charge flow. This method allows checking the insulation state between all low-voltage networks. The detected voltage values can be compared to threshold values, and the time curves of the detected voltages can be compared to the induced voltage change using temporal correlation analysis.

In an alternative approach, the induced voltage change can be caused by a power flow from the low-voltage network to the high-voltage supply system, with the DC/DC converter operated as a step-up converter, resulting in a voltage drop on the associated supply bus. In another approach, power flows from the high-voltage supply system to the low-voltage network, with the DC/DC converter operated as a step-down converter, raising the supply bus voltage from a regular operating voltage (e.g., ˜12 V) to a higher voltage (e.g., ˜14 V to ˜14.5 V). During the voltage change, the voltages on the supply buses of other low-voltage networks are monitored. Ideally, these should remain unaffected; otherwise, an insulation fault is indicated.

One advantage of this method and arrangement is the ability to check insulation without additional components or modifications to the supply arrangement, merely by activating the DC/DC converters accordingly. This allows regular, cost-effective insulation checks, enhancing the availability and safety of a vehicle's low-voltage supply system.

Voltage detection may be carried out using a dedicated sensor system. The low-voltage networks include at least one voltage sensor for detecting the voltage on each supply bus, with the detected voltage relayed to a control device.

As used herein, ‘low-voltage’ refers to voltages up to 60 V, such as ˜12 V or ˜48 V, and ‘high-voltage’ refers to voltages significantly above 60 V, such as several hundred volts (˜400 V or ˜800 V).

The energy storage device is typically an electric accumulator, such as a battery or a capacitor, specifically a supercapacitor (supercap).

The control device may combine hardware and software, such as program code executed on a microcontroller or microprocessor. Alternatively, it may be an application-specific integrated circuit (ASIC) or a field-programmable gate array (FPGA).

The vehicle is primarily a motor vehicle, particularly an electric or hybrid vehicle, but it could also be another electrified land vehicle, a rail vehicle, a watercraft, an aircraft, or a spacecraft, such as a drone or air taxi.

A safety-critical low-voltage consumer is one necessary for automated driving functions, like a steering system, braking system, or control processor. A non-safety-critical low-voltage consumer, like an infotainment system or seat heater, is not necessary for automated vehicle functions.

Before carrying out the insulation check measures, some low-voltage consumers are deactivated or maintained in a deactivated state to minimize their influence on voltage detection and prevent the voltage change from affecting them. Alternatively or additionally, non-safety-critical low-voltage consumers are disconnected from the supply bus via a semiconductor switch to achieve the same effects.

In some examples, the voltage change is induced as a pulse, sharply defined in time, making it easier to recognize subsequent voltage changes on other supply buses. The pulse may last several seconds, such as 10 or 20 seconds, allowing lower-resolution, cost-effective detection and transmission via CAN or LIN bus.

In some examples, the measures are performed consecutively for all low-voltage networks, checking them against each other. The voltage change is induced on a rotational basis among the networks, with voltages on the other supply buses detected and evaluated.

In some examples, the measures are conducted outside regular vehicle operation to prevent interference from power fluctuations due to varying power consumption.

In some examples, the measures are conducted after the vehicle is started or shut off, ensuring regular insulation checks. Measures may be taken immediately after the vehicle starts, before it is released for driving, and after shutoff, completing the method before fully shutting down the vehicle.

In some examples, the method is initiated by a diagnostic command from a central control center, such as a vehicle manufacturer's, allowing the insulation of vehicle networks to be checked on demand. If an insulation fault is detected, the central control center can take measures, such as directing the vehicle to a repair shop.

In some examples, the insulation is checked regularly, promptly detecting faults to reduce or prevent damage.

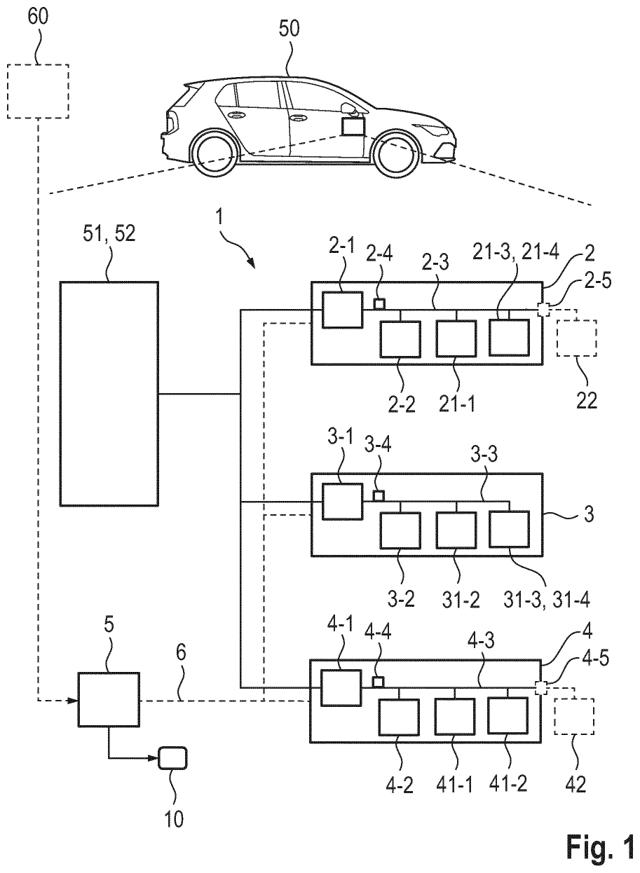

FIG. 1 shows a schematic representation of embodiments of the low-voltage supply arrangement 1 for a vehicle 50. The vehicle 50 is, in particular, an electric or hybrid vehicle, specifically a vehicle that operates in an automated or semi-automated manner. The vehicle 50 includes a high-voltage supply system 51, particularly a high-voltage battery 52. The method described in the present disclosure will be explained in greater detail based on the low-voltage supply arrangement 1.

The low-voltage supply arrangement 1 consists of three low-voltage networks 2, 3, 4. Each of the low-voltage networks 2, 3, 4 may include a DC/DC converter 2-1, 3-1, 4-1, and an energy storage device 2-2, 3-2, 4-2. The DC/DC converters 2-1, 3-1, 4-1 are connected to the high-voltage supply system 51, specifically the high-voltage battery 52, of the vehicle 50. They are also connected to the energy storage device 2-2, 3-2, 4-2 and a supply bus 2-3, 3-3, 4-3 for supplying low-voltage consumers 21-x, 31-x, 41-x. Additionally, the low-voltage networks 2, 3, 4 include voltage sensors 2-4, 3-4, 4-4 at the respective supply buses 2-3, 3-3, 4-3.

The energy storage devices 2-2, 3-2, 4-2 are primarily batteries, although they can also be other electric energy accumulators, such as capacitors or supercapacitors (supercaps).

Safety-critical low-voltage consumers 21-x, 31-x, 41-x are distributed redundantly among the low-voltage networks 2, 3. These safety-critical low-voltage consumers 21-x, 31-x, 41-x may include steering systems 21-1, 41-1 and braking systems 31-2, 41-2. A primary control processor 31-3, equipped with a first surroundings sensor system 31-4, serves as a safety-critical low-voltage consumer 31-x and is connected to the supply bus 3-3 of the low-voltage network 3. A secondary control processor 21-3, equipped with a second surroundings sensor system 21-4, is connected to the supply bus 2-3 of the low-voltage network 2.

The primary control processor 31-3 is responsible for automated driving functions and trajectory planning. It can also perform safety maneuvers if necessary. The secondary control processor 21-3 is similarly capable of executing safety maneuvers if required.

The low-voltage supply arrangement 1 also includes a control device 5. The control device 5 is connected to the DC/DC converters 2-1, 3-1, 4-1 and the voltage sensors 2-4, 3-4, 4-4 via at least one communication link 6, typically through a communication bus such as CAN and/or LIN bus.

The low-voltage networks 2, 3, and 4 are galvanically isolated from each other using transformer cores in the DC/DC converters 2-1, 3-1, and 4-1. The communication links 6 are high-resistance and may also include optocouplers and/or light guides to prevent charge flow.

Each low-voltage network 2, 3, and 4 should be configured to satisfy a safety integrity level according to ASIL B.

The control device 5 is responsible for checking insulation between the low-voltage networks 2, 3, and 4. This is done by: Applying a voltage change to the high-voltage supply system 51 or the supply buses 2-3, 3-3, and 4-3 of one low-voltage network using the respective DC/DC converter 2-1, 3-1, or 4-1; Detecting the voltage on the supply buses 2-3, 3-3, and 4-3 of the other low-voltage networks using voltage sensors 2-4, 3-4, and 4-4; Evaluating the detected voltages; and deriving and outputting a checking decision 10.

Hereafter, the procedure will be described in greater detail, wherein it is assumed, by way of example, that the voltage change is carried out by the DC/DC converter 2-1 of the low-voltage network 2, while the voltages on the supply buses 3-3, 4-3 of the other two low-voltage networks 3, 4 are detected by means of the voltage sensors 3-4, 4-4 at the same time.

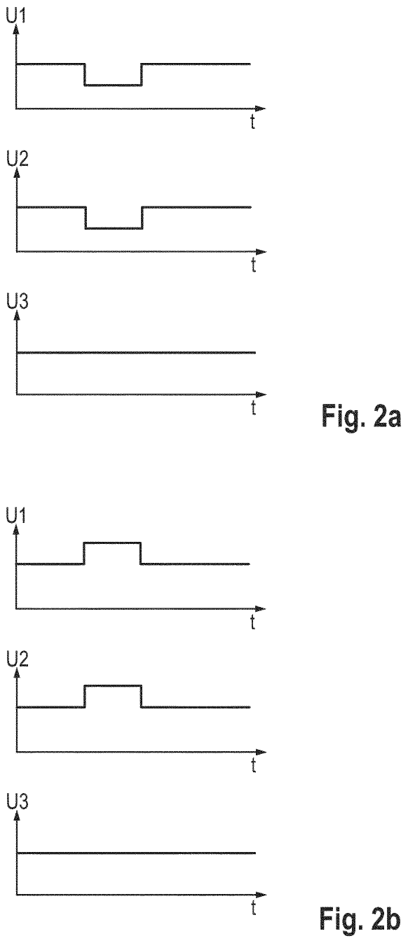

FIGS. 2a and 2b show schematic representations of voltages U1, U2, U3 on the supply buses 2-3, 3-3, 4-3 (FIG. 1) of the three low-voltage networks 2, 3, 4 over the course of the time during which the measures of the method are carried out.

FIG. 2a shows an alternative in which a voltage is applied to the high-voltage supply system 51. The DC/DC converter 2-1 acts as a step-up converter and transmits power from the low-voltage network 2 to the high-voltage supply system 51. As a result, the voltage U1 drops during the pulse because the energy storage device 2-2 is no longer able to maintain the target voltage (e.g., ˜12 V) due to the power flow. The voltages U2 and U3 on the supply buses 3-3 and 4-3 are measured during the application process. For example, assume that there is an insulation fault between the low-voltage networks 2 and 3, but no fault between the low-voltage networks 2 and 4. While the voltage pulse is applied to the high-voltage supply system 51, charges flow between the low-voltage networks 3 and 2, causing the voltage U2 to also drop. On the other hand, the voltage U3 of the insulated supply bus 4-3 remains constant because no charges can flow between the fault-free low-voltage networks 2 and 4

FIG. 2b shows another alternative in which a voltage is applied to the supply bus 2-3 of the low-voltage network 2 (shown in FIG. 1). In this example, the DC/DC converter 2-1 acts as a step-down converter, as it does during regular operation, and transmits power from the high-voltage supply system 51 to the supply bus 2-3 of the low-voltage network 2. In this case, the DC/DC converter 2-1 briefly increases the voltage U1, in a pulse-like manner, from the regular operating voltage (e.g., ˜12 V) to a higher voltage (e.g., ˜14 to 14.5 V). Consequently, the voltage U1 increases during the pulse. The voltages U2 and U3 on the supply buses 3-3 and 4-3 are measured during the application process. For example, assume that there is an insulation fault between the low-voltage networks 2 and 3, but no fault between the low-voltage networks 2 and 4. While the voltage pulse is applied to the supply bus 2-3, charges flow between the low-voltage networks 2 and 3, causing the voltage U2 to increase. Meanwhile, the voltage U3 of the insulated supply bus 4-3 remains constant because no charges can flow between the fault-free low-voltage networks 2 and 4

Proceeding from the behavior of the voltages U2 and U3 in the two cases outlined in FIGS. 2a and 2b (insulation fault, no insulation fault), the detected voltages U2 and U3 are evaluated. It can be checked whether a voltage drop (FIG. 2a) or a voltage increase (FIG. 2b) occurs while the pulse-shaped voltage change is being impressed on the supply buses 3-3, 4-3 of the other low-voltage networks 3, 4. The voltages U2 and U3 detected in a time-resolved manner are compared to suitable threshold values for this purpose. Furthermore, it is also possible to determine and evaluate a change or an increase in the voltages U2 and U3.

If a voltage drop (FIG. 2a) or a voltage increase (FIG. 2b) is recognized for the respective other voltages U2 and U3, an insulation fault is established between the respective low-voltage networks 2, 3, 4. The evaluation is carried out by the control device 5 (FIG. 1). Based on the evaluation result, the control device 5 derives and outputs a checking decision 10, for example, as an analog or digital signal or a data packet. In the illustrated example, the checking decision 10 reads: “Insulation fault between low-voltage networks 2 and 3; no insulation fault between low-voltage networks 2 and 4.”

In some examples, measures may be carried out consecutively for all low-voltage networks 2, 3, 4. This may be done by impressing the voltage change on a rotational basis by means of the respective DC/DC converter 2-1, 3-1, 4-1, and detecting and evaluating the voltages U1, U2, U3 on the supply buses 2-3, 3-3, 4-3 of the respective other low-voltage networks 2, 3, 4. In particular, a sequence for the low-voltage supply arrangement 1 shown in FIG. 1 may be as follows:
1) impressing the voltage change on the supply bus 2-3 by means of the DC/DC converter 2-1 and simultaneously detecting the voltages U2, U3 of the supply buses 3-3, 4-3 of the low-voltage networks 3 and 4;
2) impressing the voltage change on the supply bus 3-3 by means of the DC/DC converter 3-1 and simultaneously detecting the voltages U1, U3 of the supply buses 2-3, 4-3 of the low-voltage networks 2 and 4; and
3) impressing the voltage change on the supply bus 4-3 by means of the DC/DC converter 4-1 and simultaneously detecting the voltages U1, U2 of the supply buses 2-3, 3-3 of the low-voltage networks 2 and 3.

The detected voltages U1, U2, U3 are subsequently evaluated as described above, and it is checked based on a respective evaluation result as to whether or not an insulation fault is present.

In some examples, the measures of the method may be carried out outside the regular operation of the vehicle 50 (FIG. 1). For this purpose, it may be communicated by a vehicle control unit (not shown) to the control device 5 when the vehicle 50 was started or shut off. After the starting process, the method can then be carried out prior to a release for driving/operating the vehicle 50. After the vehicle has been shut off, the method is carried out before the vehicle 50 switches fully into idle mode.

In some examples, the measures may be done using a diagnostic command 20 which is received from a central control center 60. The diagnostic command 20 can, for example, be received by means of a communication device (not shown) of the vehicle 50 and transmitted to the control device 5, which then launches the measures of the method.

In some examples, at least some of the low-voltage consumers 21-x, 31-x, 41-x supplied via the supply buses 2-3, 3-3, 4-3 are deactivated and/or maintained in a deactivated state before the measures are carried out.

In some examples, the insulation is checked on a regular basis. For this purpose, for example, fixedly predefined checking times or temporal checking intervals can be established, which are adhered to by the control device 5 for checking.

As an alternative or in addition, it is furthermore provided that not safety-critical low-voltage consumers 22, 42 (FIG. 1) are disconnected from the particular supply bus 2-3, 4-3 before the insulation is checked by means of a semiconductor switch 2-5, 4-5. For example, the semiconductor switches 2-5, 4-5 are activated for this purpose by means of the control device 5 via the communication link 6.

### LIST OF REFERENCE SIGNS

1 low-voltage supply arrangement
2 low-voltage network
2-1 DC/DC converter
2-2 energy storage device
2-3 supply bus
2-4 voltage sensor
2-5 semiconductor switch
3 low-voltage network
3-1 DC/DC converter
3-2 energy storage device
3-3 supply bus
3-4 voltage sensor
4 low-voltage network
4-1 DC/DC converter
4-2 energy storage device
4-3 supply bus
4-4 voltage sensor
4-5 semiconductor switch
5 control device
6 communication link
10 checking decision
20 diagnostic command
21-x low-voltage consumer
21-1 steering system
21-3 secondary control processor
21-4 second surroundings sensor system
22 not safety-critical low-voltage consumer
31-x low-voltage consumer
31-2 braking system
31-3 primary control processor
31-4 first surroundings sensor system
41-x low-voltage consumer
41-1 steering system
41-2 braking system
42 not safety-critical low-voltage consumer
50 vehicle
51 high-voltage supply system
52 high-voltage battery
60 control center
t time
U1 voltage (supply bus 2-3)
U2 voltage (supply bus 3-3)
U3 voltage (supply bus 4-3)

1-8. (canceled)

9. A method for checking insulation between galvanically-isolated low-voltage networks of a vehicle, each of the low-voltage networks comprising a DC/DC converter, an energy storage device, and a supply bus for supplying low-voltage consumers, each DC/DC converter being configured to connect to a high-voltage supply system and to the energy storage device and the supply bus, the method comprising:
impressing a voltage change on the high-voltage supply system or on the supply bus of one of the low-voltage networks by means of the DC/DC converter of said low-voltage network;
detecting a respective voltage on the supply buses of at least the other low-voltage networks;
evaluating the detected voltages; and
deriving and outputting a checking decision,
(i) wherein impressing the voltage change comprises deactivating and/or maintaining in a deactivated state at least some of the low-voltage consumers supplied via the supply buses before the voltage change is impressed, and/or
(ii) wherein impressing the voltage change comprises disconnecting non-safety-critical low-voltage consumers from the respective supply bus before the insulation is checked by means of a semiconductor switch.

10. The method of claim 9, wherein impressing the voltage change comprises impressing the voltage change in the form of a pulse.

11. The method of claim 9, wherein impressing the voltage change comprises consecutively impressing the voltage change for all low-voltage networks.

12. The method of claim 9, wherein impressing the voltage change is carried out when the vehicle is not in active operation.

13. The method of claim 9, wherein impressing the voltage change is carried out after the vehicle has been started and/or after the vehicle has been shut off.

14. The method of claim 9, wherein impressing the voltage change is initiated by a diagnostic command received from a central control center.

15. The method of claim 9, wherein the insulation is checked on a periodic basis.

16. A low-voltage supply system for a vehicle, comprising:
a plurality of galvanically-isolated low-voltage networks, each low-voltage network comprising:
a DC/DC converter configured to connect to a high-voltage supply system;
an energy storage device; and
a supply bus for supplying low-voltage consumers;
a control device configured to:
impress a voltage change on the high-voltage supply system or on the supply bus of one of the low-voltage networks by means of the DC/DC converter of said low-voltage network;
detect a respective voltage on the supply buses of at least the other low-voltage networks;
evaluate the detected voltages; and
derive and output a checking decision, wherein the control device is further configured to:
(i) deactivate and/or maintain in a deactivated state at least some of the low-voltage consumers supplied via the supply buses before the voltage change is impressed, and/or
(ii) disconnect non-safety-critical low-voltage consumers from the respective supply bus before the insulation is checked by means of a semiconductor switch.

17. The low-voltage supply system of claim 16, wherein the control device is configured to impress the voltage change in the form of a pulse.

18. The low-voltage supply system of claim 16, wherein the control device is configured to consecutively impress the voltage change for all low-voltage networks.

19. The low-voltage supply system of claim 16, wherein the control device is configured to impress the voltage change when the vehicle is not in active operation.

20. The low-voltage supply system of claim 19, wherein the control device is configured to impress the voltage change after the vehicle has been started and/or after the vehicle has been shut off.

21. The low-voltage supply system of claim 16, wherein the control device is configured to initiate the voltage change by a diagnostic command received from a central control center.

22. The low-voltage supply system of claim 16, wherein the insulation is checked on a periodic basis.

21. A low-voltage supply arrangement for a vehicle, comprising:
a plurality of low-voltage networks that are galvanically isolated from one another, each of the low-voltage networks comprising a DC/DC converter configured to connect to a high-voltage supply system and to an energy storage device and a supply bus for supplying low-voltage consumers;
a control device configured to carry out a check of insulation between the low-voltage networks by:
impressing a voltage change on the high-voltage supply system or on the supply bus of one of the low-voltage networks by means of the DC/DC converter of said low-voltage network;
receiving a respective voltage detected on the supply buses of at least the other low-voltage networks;
evaluating the detected voltages; and
deriving and outputting a checking decision,
wherein the control device is further configured to:
(i) deactivate or maintain in a deactivated state at least some of the low-voltage consumers supplied via the supply buses before the voltage change is impressed, and/or
(ii) disconnect non-safety-critical low-voltage consumers from the respective supply bus before the insulation is checked via a semiconductor switch.

22. The low-voltage supply arrangement of claim 21, wherein the control device is configured to impress the voltage change in the form of a pulse.

23. The low-voltage supply arrangement of claim 21, wherein the control device is configured to consecutively impress the voltage change for all low-voltage networks.

24. The low-voltage supply arrangement of claim 21, wherein the control device is configured to impress the voltage change when the vehicle is not in active operation.

25. The low-voltage supply arrangement of claim 24, wherein the control device is configured to impress the voltage change after the vehicle has been started and/or after the vehicle has been shut off.

26. The low-voltage supply arrangement of claim 21, wherein the control device is configured to initiate the voltage change by a diagnostic command received from a central control center.

27. The low-voltage supply arrangement of claim 21, wherein the insulation is checked on a periodic basis.

28. The low-voltage supply arrangement of claim 21, wherein the control device is configured to compare the detected voltages to threshold values and perform a temporal correlation analysis to evaluate the detected voltages.
